(19) United States
(12) Patent Application Publication
(10) Pub. No.: US 2007/0176798 A1
(43) Pub. Date: Aug. 2, 2007

(54) SEMICONDUCTOR DEVICE INCLUDING A HIGH VOLTAGE DEVICE

(76) Inventor: Jung Ho Kim, Seoul (KR)

Correspondence Address: SHERR & NOURSE, PLLC, 620 HERNDON PARKWAY, SUITE 200, HERNDON, VA, 20170, US

(21) Appl. No.: 11/616,281

(22) Filed: Dec. 26, 2006

(30) Foreign Application Priority Data
Dec. 29, 2005 (KR) 10-2005-0133189

(51) Int. Cl. H03M 1/22

(52) U.S. Cl. 341/11

(57) ABSTRACT

Embodiments relate to a high voltage device, a semiconductor device including the same and a method of manufacturing the same. The high voltage device may include a semiconductor substrate provided with at least a high voltage device, an isolation layer formed at an area where each device is isolated on the semiconductor substrate, a gate electrode formed on the semiconductor substrate, an insulating layer sidewall formed on both sides of the gate electrode, a source region and a drain region formed by implementing an impurity ion implantation process onto the semiconductor substrate, a first interlayer dielectric formed on the semiconductor substrate, a metal interconnection including at least a PCM pad penetrating through the first interlayer dielectric and connected to the high voltage device for a PCM measurement and a passivation layer for protecting at least one of the PCM pad and/or a PCM test pad.

The present application claims priority under 35 U.S.C. 119 and 35 U.S.C. 365 to Korean Patent Application No. 10-2005-0133189 (filed on Dec. 29, 2005), which is hereby incorporated by reference in its entirety.

### BACKGROUND

A high voltage device may be used when a high voltage or a high current output is necessary, for example in motor driving, etc., or when a high voltage input is applied from an external system.

Since most inner circuits do not require a high voltage, a high voltage driving part and a low voltage driving part may be simultaneously provided on a single chip.

Hereinafter, a method of manufacturing a related art high voltage device will be described with reference to the attached drawings.

FIGS. 1A-1E are example cross-sectional diagrams to illustrate a method of manufacturing a high voltage device according to the related art.

Referring to FIG. 1A, an active area and an isolation region may be defined on semiconductor substrate 101 on which a low concentration epitaxial layer may be formed. Isolation layer 102 may be formed on an isolation region through a shallow trench isolation (STI) process.

Referring to FIG. 1B, gate insulation layer 103 and a conductive layer (for example, a high concentration multi-crystalline silicon layer) may be sequentially deposited on the entire surface of semiconductor substrate 101 on which isolation layer 102 may be formed. Then, gate electrode 104 may be formed by selectively removing the conductive layer and gate insulation layer 103.

Next, a photoresist film may be coated and then an exposing and developing process may be performed to pattern the photoresist film. Then, a low concentration p-type impurity ions may be implanted onto semiconductor substrate 101 using the patterned photoresist film as a mask, and may form source region (p-type diffusion region) 105 on a surface of semiconductor substrate 101.

An insulation layer may be deposited on a surface of semiconductor substrate 101 and an etch-back process may be performed to form insulation layer sidewall 106 on both sides of gate electrode 104.

A second photoresist film may be coated on a surface of semiconductor substrate 101, and then may be patterned through an exposing and developing process.

High concentration n+ type impurity ions may be implanted by using the patterned second photoresist film as a mask to form drain region (a floating diffusion region) 107.

Referring to FIG. 1C, interlayer dielectric 108 may be formed on a surface of semiconductor substrate 101 including gate electrode 104.

Referring to FIG. 1D, interlayer dielectric 108 may be selectively removed, for example through a dual damascene process, and may expose prescribed surface portions of gate electrode 104, each source region 105 and drain region 107, and may thereby form contact hole 109.

After that, metal thin film 110a may be deposited on a surface of semiconductor substrate 101 including contact hole 109 as a primary metal process among the manufacturing processes of the high voltage device.

Referring to FIG. 1E, metal thin film 110a may be selectively removed to form metal interconnection 110.

After completing the primary process of forming metal interconnection 110, PCM (process control module) measurement may be performed to obtain a rapid feedback for the high voltage device. PCM test pad 100 and PCM pad 100a or 100b may be subject to a short circuit or connection by the high voltage. The PCM measurement may be implemented to inspect a defect rate of the high voltage device during the manufacturing process of the high voltage device. Through the PCM measurement, resistivity, voltage, break down voltage, etc. may be examined using the interconnection assigned as a PCM pad and PCM test pad 100 provided at the cutting region of semiconductor substrate 101.

Accordingly, the PCM measurement may be impossible before second and third manufacturing processes for a high voltage device. That is, the PCM measurement may only be possible after implementing a multi-layered metal interconnection process and a passivation process. Therefore, the manufacturing process of the high voltage device may not provide rapid feedback, which may result in great time consumption and loss of semiconductor substrates.

Accordingly, a high voltage device and a method of manufacturing the same may be necessarily required to increase the yield rate of high voltage semiconductor devices, to remove unnecessary processes, and to rapidly identify defects of the substrate.

### SUMMARY

Embodiments relate to a high voltage device and a method of manufacturing the same. Embodiments relate a high voltage device and a method of manufacturing the same, in which a PCM (process control module) measurement may be performed after a primary metal interconnection process may have been completed in the process of manufacturing the high voltage device. A rapid process feedback may be possible, which may prevent the loss of a semiconductor substrate.

Embodiments relate to a high voltage device and a method of manufacturing the same, that may be capable of enabling safe and correct PCM measurement after primarily forming a metal interconnection.

In embodiments, a high voltage device may include a semiconductor substrate provided with at least a high voltage device, an isolation layer formed at an area where each device is isolated on the semiconductor substrate, a gate electrode formed on the semiconductor substrate, an insulating layer sidewall formed on both sides of the gate electrode, a source region and a drain region formed by implementing an impurity ion implantation process onto the semiconductor substrate, a first interlayer dielectric formed on the semiconductor substrate, a metal interconnection including at least a PCM pad penetrating through the first interlayer dielectric and connected to the high voltage device for a PCM measurement and a passivation layer for protecting at least one of the PCM pad and/or a PCM test pad.

In embodiments, a semiconductor device may include a semiconductor substrate, a high voltage device formed on the semiconductor substrate, a first interlayer dielectric covering an upper portion of the high voltage device, a metal interconnection including at least a PCM test pad penetrating through the first interlayer dielectric and connected to the high voltage device for a PCM measurement and a passivation layer for protecting at least one of the PCM test pad and/or PCM pad and without protecting at least one portion of the metal interconnection.

Embodiments relate to a method of manufacturing a semiconductor device. According to embodiments, a method may include protecting a PCM pad and/or a PCM test pad penetrating through a first interlayer dielectric and being connected to a high voltage device by means of a passivation layer and implementing a PCM measurement even if a high voltage is applied between the PCM pad and the PCM test pad while preventing a short or a connection from occurring between PCM pad and the PCM by means of the passivation layer.

In embodiments, a method of manufacturing a semiconductor device may include forming an isolation layer on a semiconductor substrate on which a low voltage area, a high voltage area, a middle voltage area and a non-active area may be defined, forming a gate electrode on the semiconductor substrate except for the isolation layer, forming an insulating layer sidewall on both sides of the gate electrode, forming a source and drain region on the semiconductor substrate, forming a first interlayer dielectric on a surface of the semiconductor substrate, forming a contact hole to expose the source and drain region under the first interlayer dielectric and the gate electrode, forming a metal interconnection at least within the contact hole, forming a passivation layer for protecting at least one of a PCM test pad and/or a PCM pad and implementing a PCM measurement at the high voltage area.

According to embodiments, the PCM measurement may be possible just after forming the first metal interconnection during the manufacturing process of the high voltage device. In addition, a passivation layer may be formed on any necessary metal interconnection. Accordingly a reliability of the PCM measurement may be further improved.

### BRIEF DESCRIPTION OF THE DRAWINGS

FIGS. 1A-1E are example cross-sectional diagrams illustrating a method of manufacturing a related art high voltage device;

FIG. 2 is an example cross-sectional diagram of a high voltage device according to embodiments; and

FIGS. 3A-3E are example cross-sectional diagrams to illustrate a method of manufacturing a high voltage device according to embodiments.

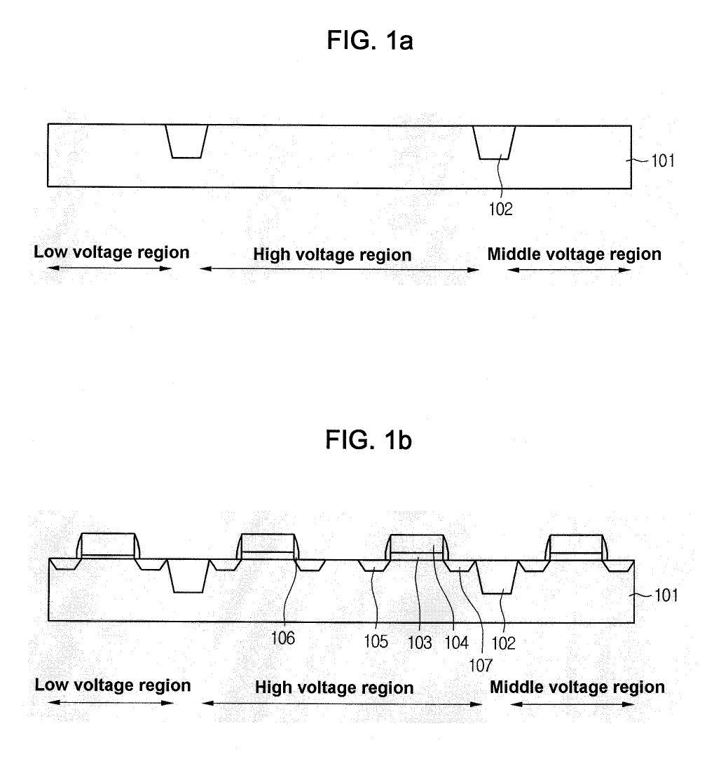

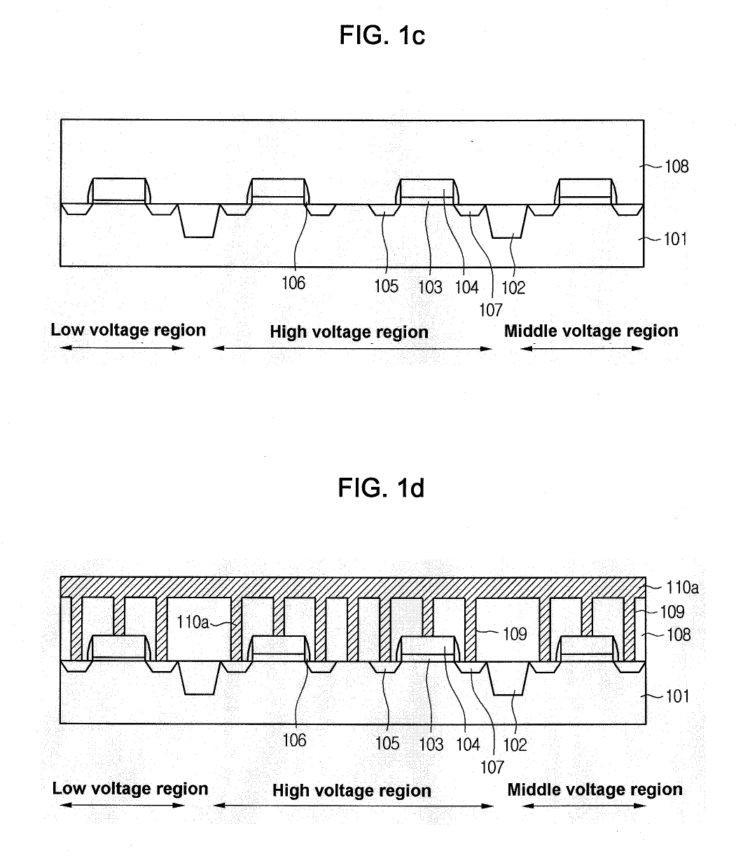

### DETAILED DESCRIPTION OF EMBODIMENTS

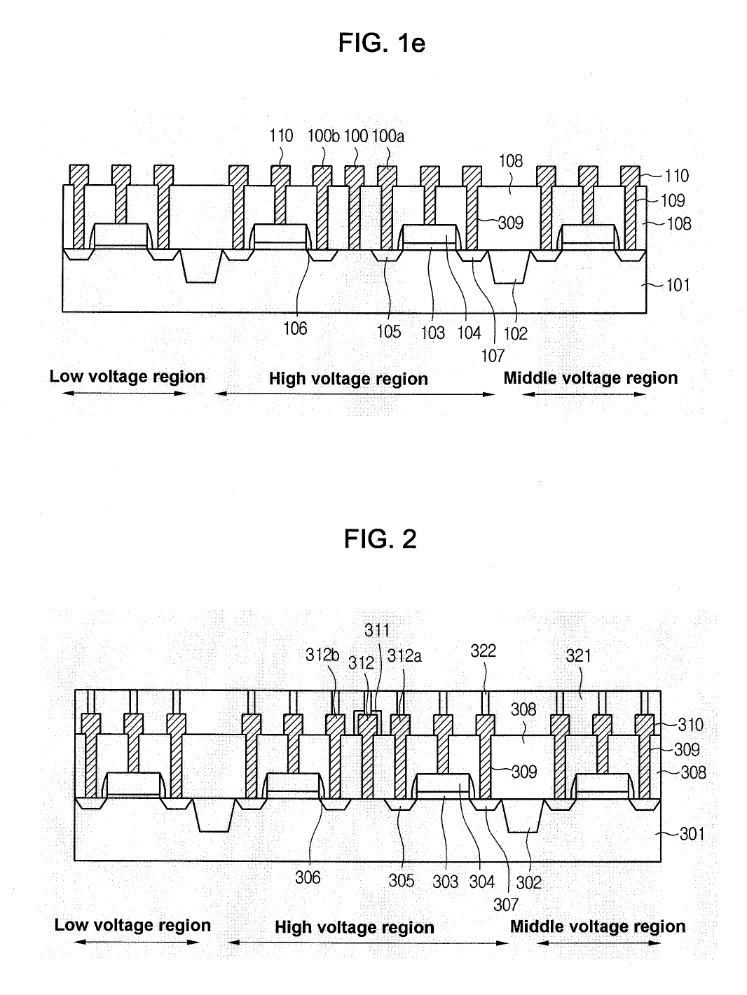

Referring to FIG. 2, a semiconductor device may include isolation layer 302 formed on semiconductor substrate 301. Low voltage region, high voltage region, middle voltage region and isolation region may be defined on semiconductor substrate 301. Gate electrodes 304 may be formed on semiconductor substrate 301 except for over isolation layer 302, for example by sequentially interposing gate insulation layer 303 and a poly-silicon layer. Source region 305 and drain region 307 may be formed, for example by implementing a dopant implantation process onto semiconductor substrate 301.

First interlayer dielectric 308 may be formed on a surface of semiconductor substrate 301. Contact hole 309 maybe formed to expose prescribed portions of source region 305 and drain region 307 and gate electrode 304 under first interlayer dielectric 308. Metal interconnection 310 may be formed in contact hole 309, PCM test pad 312 and respective PCM pad 312a and 312b for a PCM measurement during measuring PCM may be formed. Passivation layer 311 to protect PCM test pad 312 and PCM pads 312a and 312b may also be formed.

In addition, second interlayer dielectric 321 may be stacked on first interlayer dielectric 308. A plurality of via holes, into which plug 322 may be buried, may be formed at second interlayer dielectric 321.

Passivation layer 311 may be formed to protect PCM pad 312. In a state in which a part making contact with plug 322 has been removed from any top surface of passivation layer 311, PCM pad 312 may be connected with plug 322. Accordingly, PCM pad 312 may be used after a plurality of multi-layered metal interconnections have been stacked.

In embodiments, the part including passivation layer 311 is not limited to PCM pad 312. In embodiments, passivation layer 311 may be formed at least on one part of metal interconnection 310 where a connection and short may be generated during the PCM measurement. Passivation layer 311 may also be formed at the region where the PCM measurement is implemented.

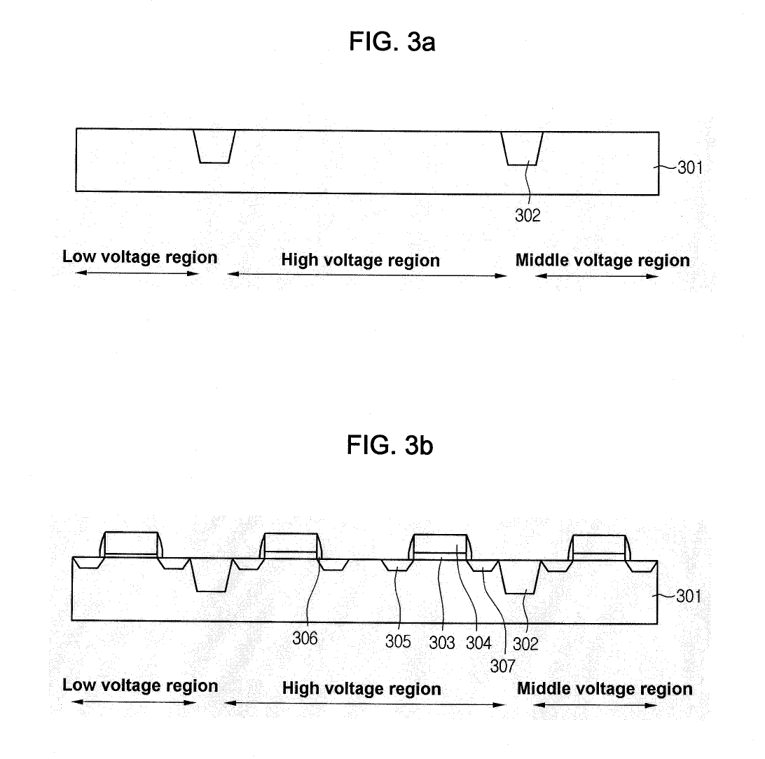

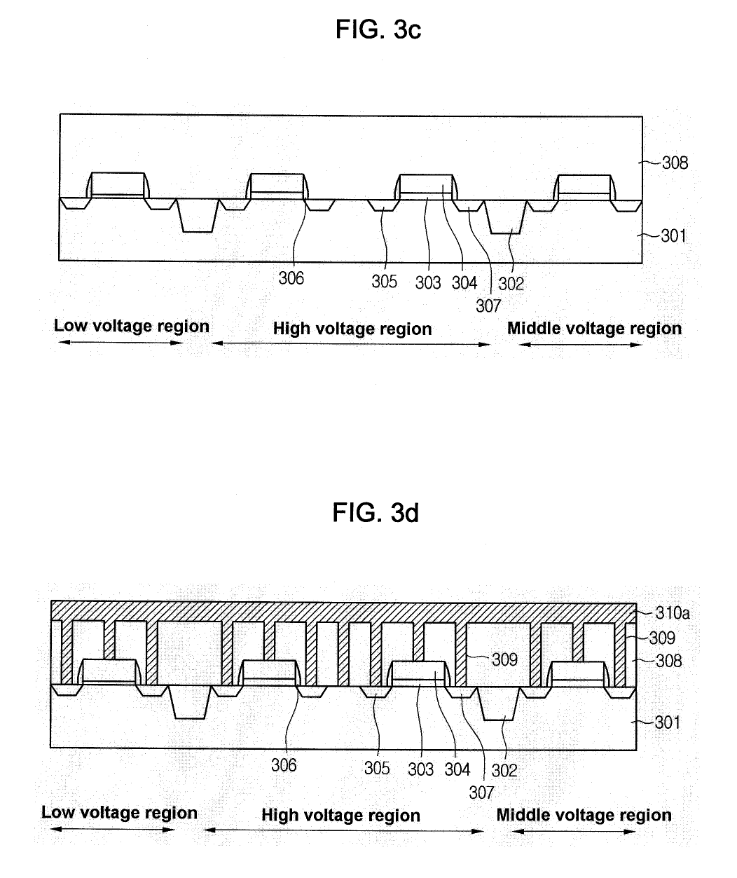

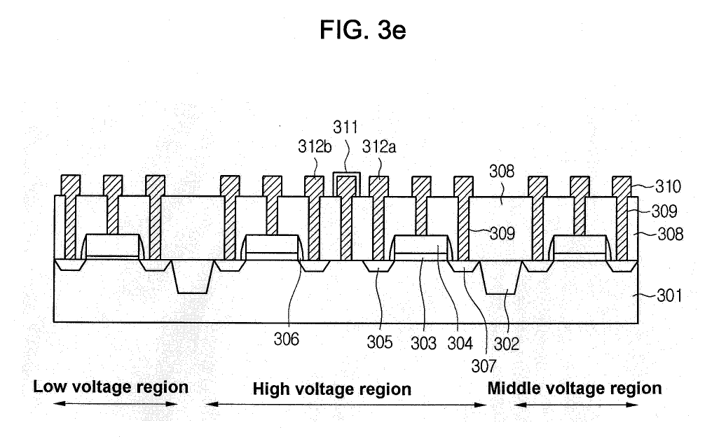

FIGS. 3A-3E are example cross-sectional diagrams to illustrate a method of manufacturing the high voltage device according to embodiments.

Referring to FIG. 3A, a device forming region and an isolation region may be defined on semiconductor substrate 301 on which a low concentration epitaxial layer may be formed through an epitaxial process. Isolation layer 302 may be formed at the isolation region by using a shallow trench isolation (STI) process.

A method of forming isolation layer 302 will be described below although not specifically depicted in the figures.

First, a pad oxide layer, a pad nitride layer, and a TEOS (tetra ethyl ortho silicate) oxide layer may be successively formed on semiconductor substrate 301. A photoresist film may be formed on the TEOS oxide layer.

The photoresist film may be exposed, for example by using a mask to define an active region and an isolation region, and may be developed for patterning. The photoresist film at the isolation region may be removed.

The pad oxide layer, the pad nitride layer, and the TEOS oxide layer at the isolation region may be selectively removed, for example by using the patterned photoresist film as a mask.

Semiconductor substrate 301 may then be etched to a prescribed depth by using the patterned pad oxide layer, pad nitride layer, and TEOS oxide layer as a mask to form a trench. The photoresist film may then be removed completely.

An inner portion of the trench may be filled with an insulating material and may form isolation layer 302 in the trench. Then, the pad oxide layer, the pad nitride layer, and the TEOS oxide layer may be removed.

Referring to FIG. 3B, gate insulating layer 303 and a conductive layer, for example, a high concentration multi-crystalline silicon layer may be deposited, for example sequentially, on a surface of semiconductor substrate 301 on which isolation layer 302 may have been formed. The conductive layer and gate insulating layer 303 may be selectively removed to form gate electrode 304.

A photoresist film may be formed on a surface of semiconductor substrate 301 and the photoresist film may be exposed and developed for patterning. Low concentration p-type impurity ions may be implanted onto semiconductor substrate 301, for example by using the patterned photoresist film as a mask, and may form source region (a p-type diffusion region) 105 at a surface portion of semiconductor substrate 301.

Subsequently, an insulating layer may be deposited on a surface of semiconductor substrate 301 and an etch-back process may be performed to form insulating layer sidewall 306 at both sides of gate electrode 304.

A second photoresist film may be coated on a surface of semiconductor substrate 301 and an exposing process and a developing process may be performed to pattern the photoresist film.

Drain region (a floating diffusion region) 307 may be formed by implanting a high concentration n+-type impurity ions onto the exposed region by using the patterned second photoresist film as a mask.

Referring to FIG. 3C, first interlayer dielectric 308 may be formed on a surface of semiconductor substrate 301 including gate electrode 304.

Referring to FIG. 3D, first interlayer dielectric 308 may be selectively removed using a dual damascene process, and may form contact hole 309. Prescribed surface portions of gate electrode 304 and each source region 305 and drain region 307 may thereby be exposed.

In embodiments, contact hole 309 formed using the dual damascene process may provide a via hole and a trench through photolithography and etching processes, even though not illustrated in the drawings. That is, after forming the via hole, a trench may be formed by selectively removing the neighboring region of the via hole, or a via hole narrower than the width of the trench may be formed after forming the trench.

Metal thin film 310a may be deposited on a surface of semiconductor substrate 301 including contact hole 309 as the first metal interconnection process among the manufacturing processes of the high voltage device.

Metal thin film 310a may be selectively removed to form metal interconnection 310. The process for forming metal thin film 310a may be implemented separately or simultaneously with the step of forming the plug in contact hole 309.

Referring to FIG. 3E, photoresist may be coated on first interlayer dielectric 308 including metal interconnection 310, and the photoresist film may be selectively removed to form passivation layer 311 on a prescribed area.

Passivation layer 311 may protect PCM pad 312 and a program to prevent the short and connection between PCM test pad 312 and PCM pads 312a and 312b used for the PCM measurement. According to embodiments, passivation layer 311 may be formed at any metal interconnection 310 where a short and a connection may be generated to prevent the generation of the short and the connection caused by the high voltage.

Referring to FIG. 3E, since the short and the connection between PCM test pad 312 and PCM pads 312a and 312b may be prevented during the PCM measurement, the PCM measurement with respect to a high voltage device and a semiconductor device including a high voltage device may be executed. According to embodiments, a reliability of the PCM measurement may be improved.

After executing the PCM measurement, second interlayer dielectric 321 and plug 322 may be sequentially stacked, as illustrated in FIG. 2. Any number of metal interconnections may be formed, and may be stacked to be six or more, according to embodiments.

In embodiments, the high voltage device, the semiconductor device having the high voltage device, and the method of manufacturing the semiconductor device according to embodiments may provide various advantages.

For example, the short and the connection between the PCM test pad and the PCM pad may be prevented by forming a passivation layer using photoresist at the PCM test pad to which a PCM measurement terminal is connected after forming the first metal interconnection during the manufacturing process of the high voltage device. In addition, since the passivation layer may be formed on any necessary metal interconnection, the reliability of the PCM measurement may be improved even further.

According to embodiments, the passivation layer may be formed only on PCM test pad 312. However, according to embodiments, the passivation layer also may be formed on PCM pads 312a and 312b. However, the short and the connection may be prevented when the passivation layer may be formed on one of the layers. Therefore, it may not be necessary to form the passivation layer on both layers

According to embodiments, a safe and correct PCM measurement may be possible. Therefore, rapid feedback may be possible during the manufacturing process of a high voltage device. Accordingly, time loss may be decreased and loss of the semiconductor substrates may be prevented.

It will be apparent to those skilled in the art that various modifications and variations can be made to embodiments. Thus, it is intended that embodiments cover modifications and variations thereof within the scope of the appended claims. It is also understood that when a layer is referred to as being “on” or “over” another layer or substrate, it can be directly on the other layer or substrate, or intervening layers may also be present.

What is claimed is:

1. A device comprising:
a semiconductor substrate having at least a high voltage device formed thereon;
a first interlayer dielectric formed over the semiconductor substrate;
a metal interconnection including at least a PCM pad penetrating through the first interlayer dielectric and being electrically connected to the high voltage device and configured for PCM measurement; and
a passivation layer formed on at least one of the PCM pad and a PCM test pad.

2. The device of claim 1, further comprising:
an isolation layer formed over an area of the semiconductor substrate to isolate devices from each other;
a gate electrode formed over the semiconductor substrate;
an insulating layer sidewall formed on both sides of the gate electrode; and
a source region and a drain region formed by performing a dopant implantation process onto the semiconductor substrate.

3. The device of claim 1, wherein the passivation layer is configured to electrically protect the at least one of the PCM pad and the PCM test pad on which the passivation layer is formed.

4. The device of claim 1, wherein the semiconductor substrate comprises a low voltage device and a middle voltage device.

5. The device of claim 1, wherein the passivation layer is formed after coating and patterning photoresist.

6. The device of claim 1, wherein the passivation layer is formed on a metal interconnection which generates a short and a connection when a high voltage is applied thereto during the PCM measurement.

7. The device of claim 1, further comprising a second interlayer dielectric formed on the passivation layer.

8. The device of claim 1, wherein a portion of the passivation layer is removed to electrically connect a metal interconnection formed above the passivation layer to the PCM pad.

9. A semiconductor device comprising:
a semiconductor substrate;
a high voltage device formed on the semiconductor substrate;
a first interlayer dielectric formed over the high voltage device;
a metal interconnection including at least a PCM pad penetrating through the first interlayer dielectric and being electrically connected to the high voltage device for a PCM measurement; and
a passivation layer formed on at least one of the PCM pad and a PCM test pad and configured to protect the at least one PCM test pad and PCM pad without protecting at least one portion of the metal interconnection.

10. The device of claim 9, wherein the PCM pad is provided at a boundary area of the high voltage device.

11. The device of claim 9, further comprising a low voltage device and a middle voltage device.

12. The device of claim 9, wherein the passivation layer is configured to protect the metal interconnection onto which a high voltage is applied.

13. The device of claim 9, further comprising a second interlayer dielectric formed over the passivation layer.

14. The device of claim 13, wherein a portion of the passivation layer and the second interlayer dielectric are removed in a process of forming a metal interconnection on the second interlayer dielectric.

15. A method comprising:
forming an isolation layer over a semiconductor substrate, wherein at least a high voltage area is defined in the semiconductor substrate;
forming a first interlayer dielectric over the semiconductor substrate;
forming a contact hole in the first interlayer dielectric to expose a source region, a drain region, and a gate electrode formed under the first interlayer dielectric in the high voltage area;
forming a metal interconnection in the contact hole, including at least a PCM pad; and
forming a passivation layer configured to protect at least one of a PCM test pad and the PCM pad.

16. The method of claim 15, further comprising:
forming the gate electrode over the semiconductor substrate;
forming an insulating layer sidewall on both sides of the gate electrode; and
forming the source region and the drain region over the semiconductor substrate.

17. The method of claim 15, wherein the passivation layer is formed through coating and patterning a photoresist.

18. The method of claim 15, further comprising implementing a PCM measurement at the high voltage area, and forming a second interlayer dielectric after implementing the PCM measurement.

19. The method of claim 18, wherein a portion of the passivation layer and the interlayer dielectric arranged with the passivation layer are removed to make an electrical connection with a metal interconnection to be formed later.

20. A method comprising:
protecting with a passivation layer at least one of a PCM pad and a PCM test pad penetrating through a first interlayer dielectric and being connected to a high voltage device; and
performing a PCM measurement even if a high voltage is applied between the PCM pad and the PCM test pad while preventing at least one of a connection and a short from occurring between the PCM pad and the PCM test pad by using the passivation layer.

21. The method of claim 20, further comprising stacking a second interlayer dielectric over the first interlayer dielectric after the PCM measurement.

22. The method of claim 21, further comprising forming a contact hole penetrating the passivation layer and the second interlayer dielectric.

23. The method of claim 22, further comprising filling an inner portion of the contact hole with a plug.
